(19) United States
(12) Patent Application Publication
(10) Pub. No.: US 2007/0015333 A1
(43) Pub. Date: Jan. 18, 2007

(54) Method for manufacturing silicon carbide semiconductor devices

(75) Inventors: Daisuke Kishimoto, Yama-gun (JP); Takeshi Tawara, Matsumoto (JP); Takashi Tsuji, Matsumoto (JP); Shunsuke Izumi, Yokosuka-shi (JP)

Correspondence Address: ROSSI, KIMMS & McDOWELL LLP., P.O. BOX 826, ASHBURN, VA, 20146-0826, US

(73) Assignee: Fuji Electric Holdings Co., Ltd., Kawasaki-ku (JP)

(21) Appl. No.: 11/452,053

(22) Filed: Jun. 13, 2006

(30) Foreign Application Priority Data
Jun. 15, 2005 (JP) JPPA 2005-174555

(51) Int. Cl. H01L 21/336

(52) U.S. Cl. 438/259; 257/E21.384

(57) ABSTRACT

A method of manufacturing a semiconductor device is disclosed that includes the treating the surface of a SiC semiconductor substrate prior to forming a gate oxide film on the SiC semiconductor substrate in order to etch the SiC semiconductor substrate by several nm to 0.1 μm with hydrogen in a reaction furnace. The treating is conducted a reduced pressure in the furnace, at a temperature of 1500° C. or higher. The manufacturing method facilitates the removal of particles and oxide residues remaining on the trench inner wall after trench etching in the manufacturing process for manufacturing a SiC semiconductor device having a fine trench-type MOS gate structure.

### CROSS REFERENCE TO RELATED APPLICATIONS

This application claims priority from application Serial No. JP 2005-174555, filed on Jun. 15, 2005, the entire contents of which are incorporated herein by reference.

### BACKGROUND OF THE INVENTION

A. Field of the Invention

The present invention relates to methods for manufacturing silicon carbide (“SiC”) semiconductor devices having an insulated gate. Specifically, the present invention relates also to methods for forming a trench-type insulated gate and to techniques for treating the surface of a SiC semiconductor device in the process of forming the trench-type insulated gate thereof. Although the surface treatment techniques according to the invention are applicable to all the SiC semiconductor devices having a trench-type insulated gate structure, the surface treatment techniques according to the invention are particularly applicable to insulated gate field effect transistors (MOSFETs), insulated gate bipolar transistors (IGBTs), and insulated gate thyristors having a trench-type insulated gate structure.

B. Description of the Related Art

The SiC semiconductor crystal exhibits a thermal conductivity higher than the thermal conductivity of the silicon (Si) crystal. The SiC semiconductor crystal is stable physically, chemically, and thermally. The band gap is 3.25 eV for 4H—SiC, which is three times as high as the band gap for Si, which is 1.12 eV. The electric field strength that causes dielectric breakdown in SiC is from 2 to 4 MV/cm, which is nearly ten times as high as the electric field strength that causes dielectric breakdown in Si, which is 0.3 MV/cm. Therefore, the SiC semiconductor crystal is an excellent material for the power semiconductor devices.

In the power semiconductor devices, the on-resistance thereof reduces in inverse proportion to the cube of the electric field strength and in proportion to the inverse of the mobility. Although the carrier mobility in the SiC semiconductor is lower than the carrier mobility in the Si semiconductor, the SiC semiconductor devices facilitate reducing the on-resistance thereof to a value that is from one to several hundredths as high as the on-resistance of the Si semiconductor device. Therefore, the SiC semiconductor devices are expected to be the power semiconductor devices of the next generation. Diodes, transistors, thyristors and such devices having various structures have been fabricated experimentally so far using SiC, and some of them have been used in practice already.

Now the SiC semiconductor devices will be described in more detail below in connection with the examples thereof. For example, since the MOSFET using a 4H—SiC crystal as the main component thereof uses a silicon oxide film for the gate oxide film thereof, an imbalance is caused between Si atoms and C atoms in the boundary between the silicon oxide film and the SiC crystal and, therefore, the interface level density is liable to be high. Since the carrier mobility in the channel (hereinafter referred to as the “channel mobility”) is low in the SiC MOSFET, the channel resistance will constitute most of the on-resistance, if the channel mobility is not improved. Therefore, it is expected that the channel resistance determines the performance limit of the MOSFET. As counter measures against the high channel resistance, a trench gate structure may be employed for the MOS gate to increase the channel density per unit area, or the (03-38) plane of 4H—SiC, the mobility of which is known to be the highest, may be used for the crystal plane for forming the MOS gate. However, these counter measures are not fundamental ones for suppressing the boundary level density to improve the channel mobility. In short, the counter measures against the high channel resistance are not always satisfactory. Therefore, in order to provide the SiC MOSFETs with better performance, it is necessary and indispensable to improve the channel mobility itself.

Publication of Unexamined Japanese Patent Application 2003-124208 (Paragraphs 0005 and 0061, and FIG. 5), discloses an invention for reducing the boundary level density in the MOS structure using a SiC crystal to improve the channel mobility. FIG. 5 and paragraph (0061) in this document describe a method for improving the channel mobility. According to the subject matter of the invention disclosed in this document, excess Si atoms are provided in advance to suppress the adverse effects posed on the interface state density by the excessive C atoms caused in the interface between the silicon oxide film and the SiC crystal by the imbalance between the number of the Si atoms and the number of the C atoms due to the oxide film formation.

However, the invention disclosed in this document is applicable only on precondition that a reliable clean surface has been obtained prior to forming a gate oxide film. It is considered that it will be hard to apply the invention disclosed in this document effectively when a clean surface is not obtained.

In the manufacturing process for manufacturing a SiC semiconductor device having a trench-type MOS gate, it becomes harder, as the trench width or the trench diameter becomes finer, to remove particles 14, oxide residues 10 and such contaminants caused in trench 8 shown in an expanded perspective view of the trench shown in FIG. 3. Moreover, surface roughness 13 is liable to be caused in trench inner wall 9 in trench 8. Since these faults are caused in advance of forming a gate insulator film, it is expected without any doubt that the gate insulator film quality will be impaired, if the gate insulator film is formed without solving the contamination problems, i.e., without removing the contaminants and the surface roughness. Therefore, it is considered that contamination problems should be solved prior to solving the problems described in Publication of Unexamined Japanese Patent Application 2003-124208. In other words, it is necessary not only to solve the problems of the imbalance between the number of Si atoms and the number of C atoms caused in the SiC crystal surface in forming a gate oxide film as described in that document, but also to remove particles, oxide residues and such contaminants remaining in the trench, surface roughness, and all such factors which deteriorate the gate insulator film quality. In the following descriptions, the amorphous surface portion of the SiC crystal including several atomic layers and the layers contaminated with oxygen atoms from the cleaning liquid are included in the particles and the oxide residues.

Especially in the step of forming trenches for a trench-gate MOSFET, the problems caused by the particles, oxide residues and such various contaminants, and by the surface roughness, occupy a greater part as the trench width or the trench diameter becomes finer. Therefore, it is a primary object to obtain a reliable clean surface as the trench width or the trench diameter becomes finer as described above.

For improving the channel mobility, it is considered that it is very important to form the SiC crystal surface, in which a MOS channel is formed, as a perfectly crystalline clean surface as much as possible and to terminate the dangling bonds (unbonded bonds) of the constituent atoms (Si atoms or C atoms) constituting the surface region with hydrogen atoms so that the surface region may be prevented from attracting contaminant atoms.

In view of the foregoing, it would be desirable to provide a method for manufacturing a SiC semiconductor device having a MOS gate structure that facilitates removing the particles and oxide residues remaining on the trench surface after trench etching. It would be especially desirable to provide a method for manufacturing a SiC semiconductor device having a fine trench-type MOS gate structure that facilitates removing the particles and oxide residues remaining on the trench surface after trench etching.

The present invention is directed to overcoming or at least reducing the effects of one or more of the problems set forth above.

### SUMMARY OF THE INVENTION

The present invention provides a method for manufacturing a SiC semiconductor device including a SiC semiconductor substrate, the method including the steps of treating the surface of the SiC semiconductor substrate with hydrogen in a reaction furnace in which the pressure is reduced, at 1500° C., or higher to etch the surface of the SiC semiconductor substrate for from several nm to 0.1 μm, forming a gate oxide film on the SiC semiconductor substrate, wherein the step of treating being conducted in advance to the step of forming. In one embodiment, the step of treating includes a step of supplying hydrogen for a carrier gas and a step of adding HCl gas to the hydrogen carrier gas to etch the surface of the SiC semiconductor substrate. In another embodiment, the step of treating includes a step of supplying hydrogen for a carrier gas and a step of adding C₃H₈ gas to the hydrogen carrier gas to etch the surface of the SiC semiconductor substrate. In yet another embodiment, the step of treating includes a step of supplying hydrogen for a carrier gas and a step of adding SiH₄ gas to the hydrogen carrier gas to etch the surface of the SiC semiconductor substrate.

In a preferred embodiment, the step of treating preferably includes a step of etching including supplying hydrogen for a carrier gas and adding C₃H₈ gas and SiH₄ gas to the hydrogen carrier gas, and a step of growing an epitaxial film with the C₃H₈ gas and the SiH₄ gas, where the rate of etching is a little bit faster than or equal to the rate of growing the epitaxial film.

The method for manufacturing a SiC semiconductor device including a SiC semiconductor substrate preferably includes a combination of two or more of the steps of treating described above.

The method preferably includes a step of growing an epitaxial film with C₃H₈ gas and SiH₄ gas.

The method according to the invention further preferably includes the steps of (i) forming trenches for a trench-type MOS gate structure in the SiC semiconductor substrate, the step of forming the trenches being conducted prior to the step of treating the surface of the SiC semiconductor substrate, and (ii) forming gate oxide films on the SiC semiconductor substrate, the step of forming the gate oxide films being conducted subsequently to the step of treating the surface of the SiC semiconductor substrate.

The major surface of the SiC semiconductor substrate, in which a trench MOS structure is formed, is preferably the (11-20) plane of the SiC crystal or a plane equivalent to the (11-20) plane; and one or more side walls of the trench are preferably the (03-38) plane of the 4H—SiC crystal for the semiconductor substrate or a plane having equivalent orientation equivalent to the (03-38) plane or the one or more side walls of the trench are preferably the (01-14) plane of the 6H—SiC crystal for the semiconductor substrate or a plane having an orientation equivalent to the (01-14) plane.

The manufacturing method according to the invention facilitates removing the particles and oxide residues left after forming trenches in the manufacturing process for manufacturing a SiC semiconductor device having a MOS gate structure and especially in the manufacturing process for manufacturing a SiC semiconductor device having a fine trench-type MOS gate structure.

Although the invention will be described below in connection with a SiC semiconductor device having a fine trench-type MOS gate structure, for which the manufacturing method according to the invention exhibits the most remarkable effects, the manufacturing method according to the invention will exhibit certain effects for the usual planar-type MOS gate structure, since it is preferable for the usual planar-type MOS gate structure to be provided with a better SiC crystal surface.

### BRIEF DESCRIPTION OF THE DRAWINGS

The foregoing advantages and features of the invention will become apparent upon reference to the following detailed description and the accompanying drawings, of which:

FIG. 1(a) is a cross sectional view showing a semiconductor substrate for a SiC semiconductor device under the manufacture thereof by a manufacturing method according to the invention;

FIG. 1(b) is another cross sectional view showing the semiconductor substrate for the SiC semiconductor device under the manufacture thereof by the manufacturing method according to the invention;

FIG. 2(a) is a cross sectional view showing the semiconductor substrate prior to the step of trench etching by the manufacturing method according to the invention;

FIG. 2(b) is another cross sectional view showing the semiconductor substrate prior to the step of trench etching by the manufacturing method according to the invention;

FIG. 3 is an expanded perspective view of a trench showing oxide residues in the trench;

FIG. 4(a) is a top plan view of the SiC semiconductor substrate with trenches formed therein and arranged at the lattice points of a planar lattice;

FIG. 4(b) is a cross sectional view along the line segment A-A of FIG. 4(a);

FIG. 5(a) is a first cross sectional view describing the process of removing oxide residues in the trench by the manufacturing method according to the invention;

FIG. 5(b) is a second cross sectional view describing the process of removing the oxide residues in the trench by the manufacturing method according to the invention;

FIG. 5(c) is a third cross sectional view describing the process of removing the oxide residues in the trench by the manufacturing method according to the invention;

FIG. 5(d) is a fourth cross sectional view describing the process of removing the oxide residues in the trench by the manufacturing method according to the invention;

FIG. 5(e) is a fifth cross sectional view describing the process of removing the oxide residues in the trench by the manufacturing method according to the invention;

FIG. 6(a) is a schematic describing at an atomic level the crystal surface roughness caused by atom deposition;

FIG. 6(b) is another schematic describing at the atomic level the atom arrangement after the etching for reducing the surface roughness;

FIG. 6(c) is still another schematic describing at the atomic level the atom arrangement after the epitaxial film growth for flattening the surface roughness;

FIG. 7 is a macroscopic cross sectional view of FIG. 2(b);

FIG. 8 is a cross sectional view of a trench MOS SiC semiconductor substrate manufactured by the method for manufacturing a SiC semiconductor device according to the invention;

### DETAILED DESCRIPTION OF SPECIFIC EMBODIMENTS

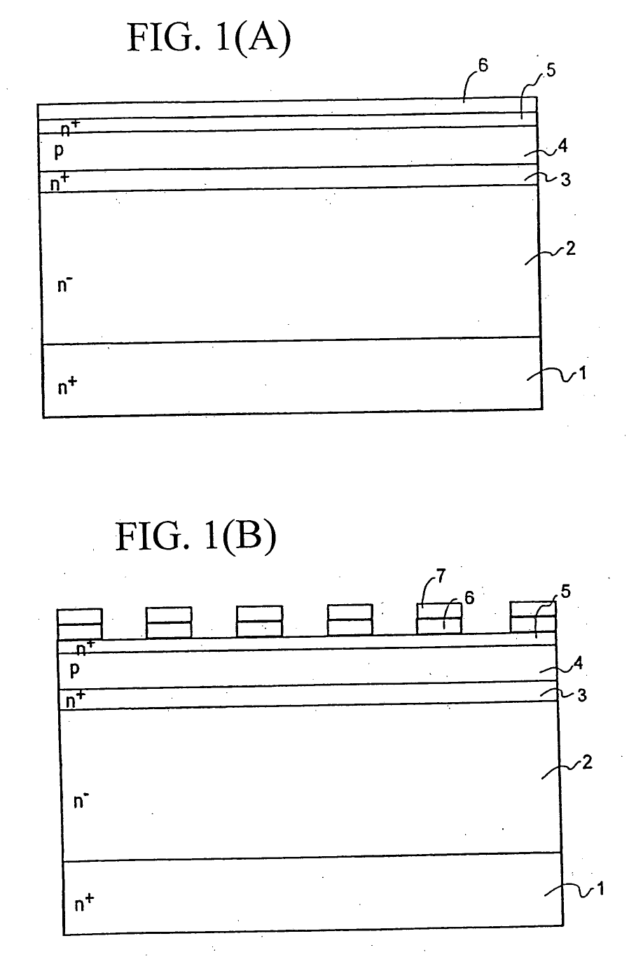

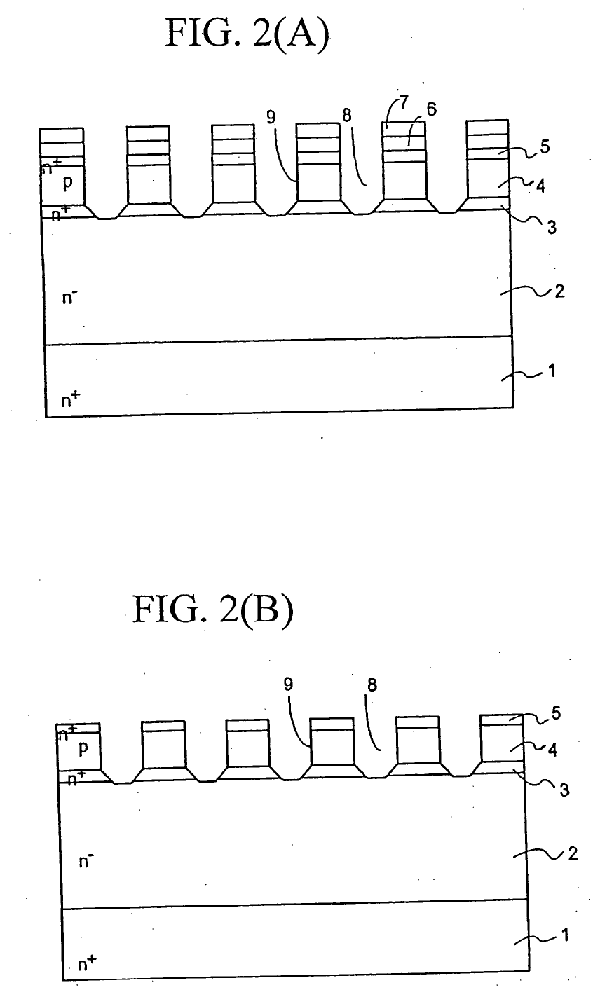

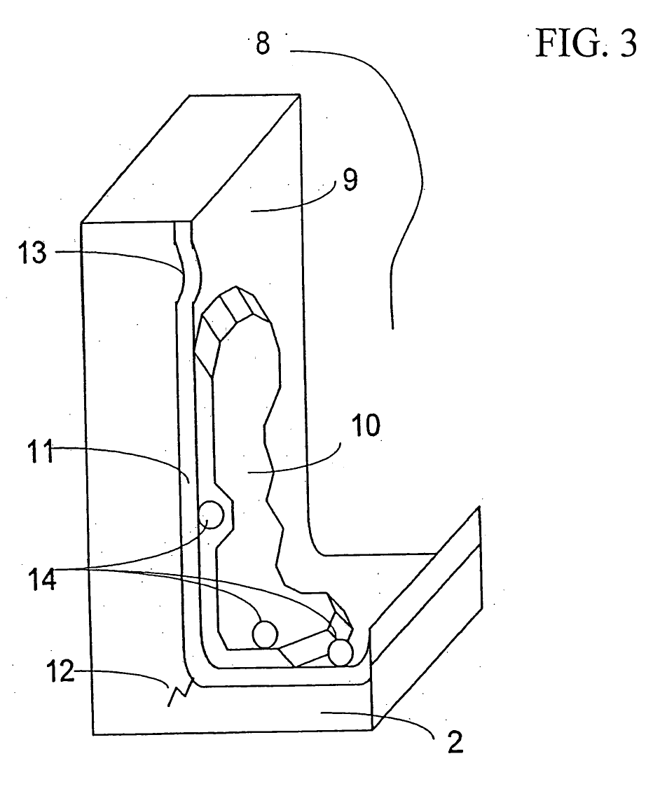

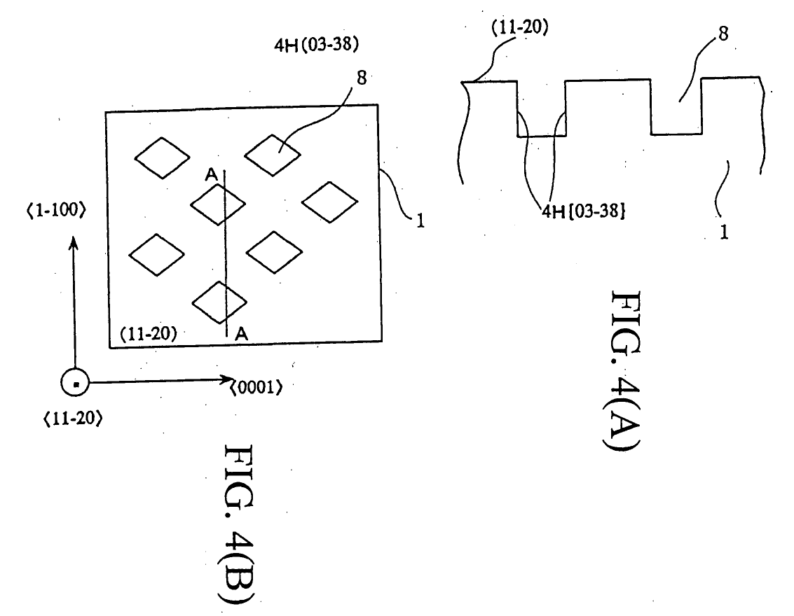

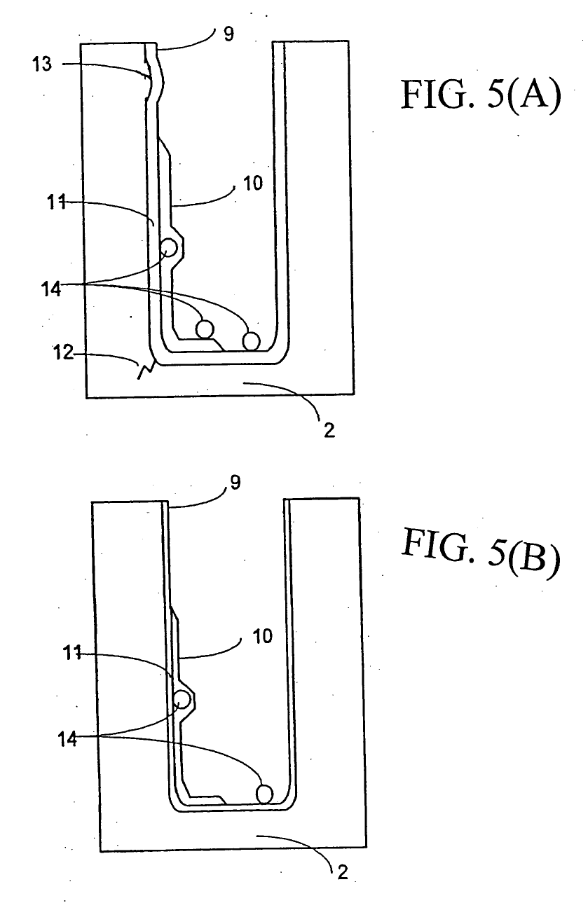

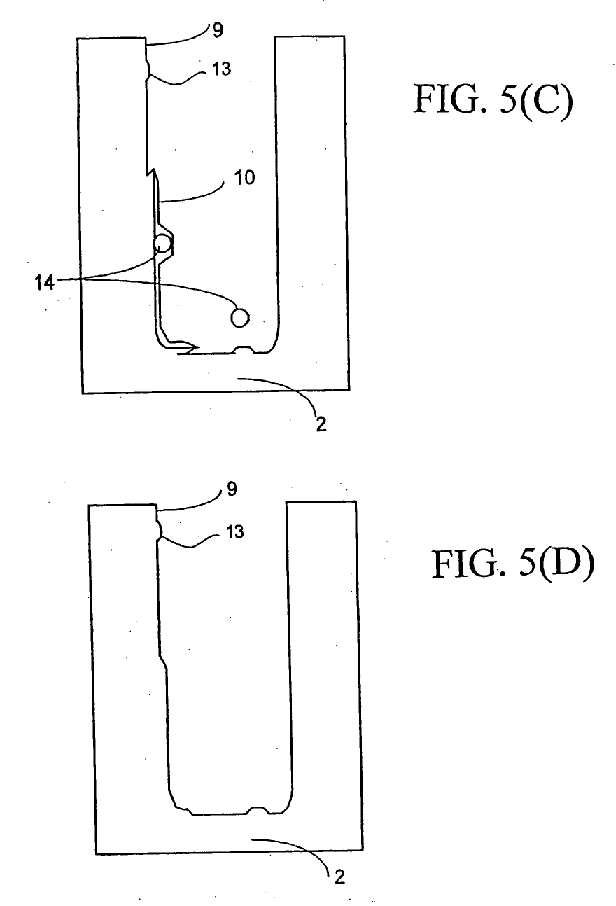

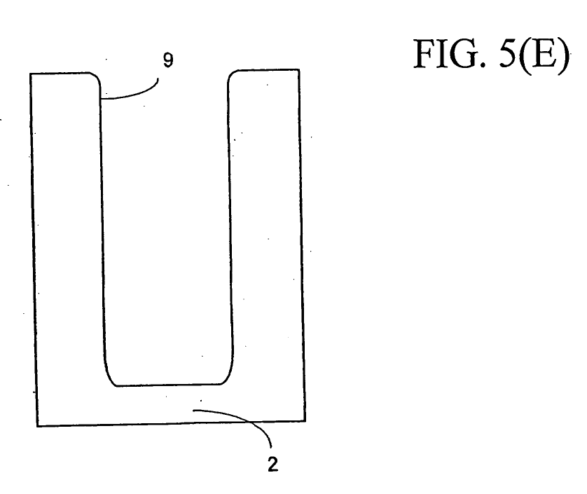

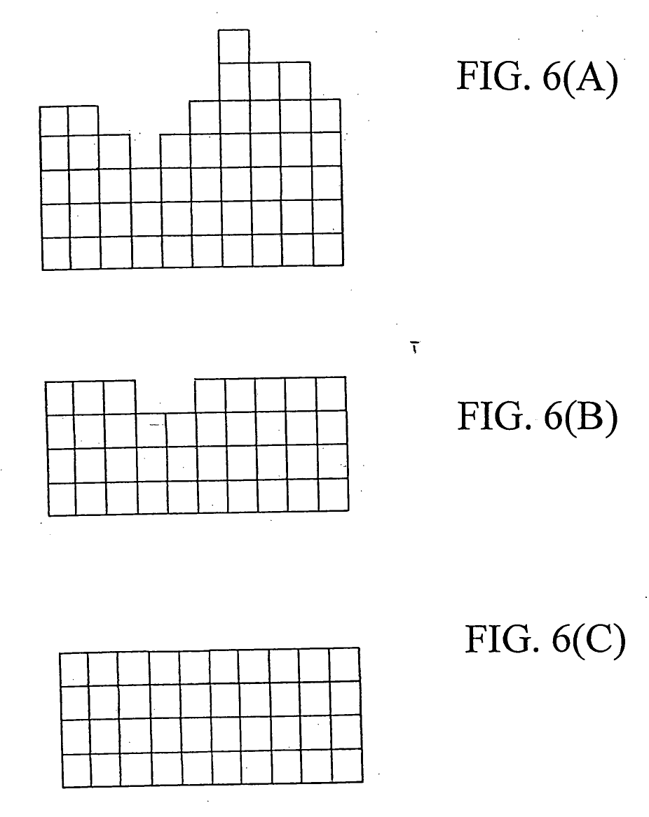

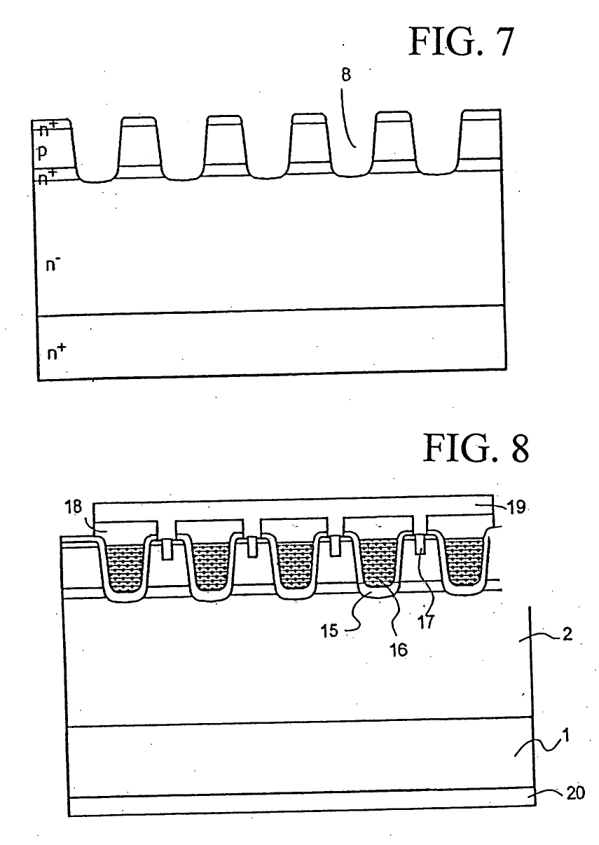

FIGS. 1(a) and 1(b) are cross sectional views showing a semiconductor substrate for a SiC semiconductor device under the manufacture thereof by a manufacturing method according to the invention. FIGS. 2(a) and 2(b) are cross sectional views showing the semiconductor substrate prior to the step of trench etching by the manufacturing method according to the invention. FIG. 3 is an expanded perspective view of a trench showing oxide residues in the trench. FIG. 4(a) is a top plan view of the semiconductor substrate with trenches having side walls formed therein. The trench side walls are formed of the (03-38) plane of 4H—SiC or the (01-14) plane of 6H—SiC. FIG. 4(b) is a cross sectional view along the line segment A-A of FIG. 4(a). FIGS. 5(a) through 5(e) are cross sectional views describing the steps of removing the oxide residues in the trench by the manufacturing method according to the invention. FIGS. 6(a) through 6(b) are schematics describing the atom deposition at an atomic level. FIG. 7 is a macroscopic cross sectional view of FIG. 2(b). FIG. 8 is a cross sectional view of a trench MOS SiC semiconductor substrate manufactured by the method for manufacturing a SiC semiconductor device according to the invention.

### First Embodiment

Now the invention will be described in detail hereinafter with reference to the accompanied drawings which illustrate the preferred embodiments of the invention. Although the invention will be described in connection with the embodiments thereof, changes and modifications are obvious to those skilled in the art without departing from the true spirit of the invention.

Although the invention will be described in connection with an n-channel trench-gate MOSFET (hereinafter referred to simply as a “UMOSFET”), the invention will be applicable also to a p-channel trench-gate MOSFET. The invention will be applicable also, as described later, to a planar-gate MOSFET that does not include any trench gate.

In the following descriptions, it is not always necessary to conduct the step of forming p-type well region 4, the step of forming n⁺-type source region 5, and the step of forming trenches 8 shown in FIG. 1(a) through FIG. 2(b) in the order of the above description. In other words, the order of these steps may be changed appropriately. However, for stabilizing the process, it is more preferable to conduct the step of forming p-type well region 4 in advance to the step of forming trenches 8.

Now the manufacture of a UMOSFET by a manufacturing method according a first embodiment of the invention will be described with reference to FIGS. 1(a) through 2(b).

First, an n⁻-type SiC layer 2 is grown by epitaxial growth on the surface portion of an n⁺-type SiC semiconductor substrate 1 having a major surface formed of an (11-20) plane and exhibiting low electrical resistance. The impurity concentration in n⁻-type SiC layer 2 is 1×10¹⁶ cm⁻³. The n⁻-type SiC layer 2 is 10 μm in thickness. The n⁻-type SiC layer 2 will work for a drift region. Then, a SiC layer 3 of 0.4 μm in thickness, which will be an n-type buffer region, is formed by epitaxial growth on n⁻-type SiC layer 2. The impurity concentration in SiC layer 3 is 2×10¹⁷ cm⁻³. Then, a p-type SiC layer 4 of 2 μm in thickness, which will be a p-type well 4, is formed by epitaxial growth on SiC layer 3. The impurity concentration in p-type SiC layer 4 is 2×10¹⁷ cm⁻³. Then, an n⁺-type SiC layer 5 of 0.5 μm in thickness, which will be an n⁺-type source region 5, is formed by epitaxial growth on p-type SiC layer 4. The impurity concentration in n⁺-type SiC layer 5 is 1×10¹⁸ cm⁻³. The surface portion of the semiconductor substrate formed as described above is treated by pyrogenic oxidation at 1100° C. for 1 hour to form a protective oxide film 6 of from 30 to 50 nm in thickness. The cross section of the semiconductor substrate with protective oxide film 6 formed thereon is shown in FIG. 1(a).

Any of the layers 3 through 5 or all the layers 3 through 5 formed as described above may be formed not by epitaxial growth but by ion implantation and by subsequent activating annealing. In the following, descriptions will be made in connection with the layers 3 through 5 formed by epitaxial growth.

Then, an Al layer of 0.5 μm in thickness is formed on the surface portion of protective oxide film 6 by sputtering (cf. FIG. 1(b)) and the Al layer is patterned through photo-processes to form Al mask 7. Trenches 8 are formed by inductive coupled plasma (ICP) etching using Al mask 7 and a gas mixture of SF₆ and O₂ (cf. FIG. 2(a)). Then, Al mask 7 and protective oxide film 6 are removed. The cross section of the semiconductor substrate with trenches 8 formed therein but Al mask 7 and protective oxide film 6 removed therefrom is shown in FIG. 2(b).

In many trench etchings by ICP etching, contamination is caused in the semiconductor surface by heavy metals, even though they are present only in trace amounts. Although the amount of contamination caused by heavy metals differs depending on the kinds of the apparatus employed and the heavy metal elements, the surface density of the heavy metal atoms in the semiconductor surface is between 1×10¹¹ cm⁻² and 1×10¹² cm⁻² in many cases. The surface density of the heavy metal contamination allowable for the electronic device process is 1×10¹¹ cm⁻² or lower. If the semiconductor surface is treated by a wet treatment using dilute hydrofluoric acid, buffered hydrofluoric acid and such a hydrofluoric acid solution in removing protective oxide film 6, most of the heavy metal contamination usually will be removed and the heavy metal contamination will be within the allowable range. Therefore, the heavy metal contamination usually does not pose any serious problem.

Since the ICP etching method and such a dry etching method bombard a crystal surface with plasmas or ions under the acceleration voltage of from several tens to several hundreds V to obtain anisotropic etching effects, the ICP etching method and such a dry etching method exhibit a secondary effect of partly destroying the crystal. As shown in FIG. 3, which is an expanded perspective view of a trench, oxide residues 10 are caused on trench inner wall 9, and amorphous SiC 11, crystal damage 12 and surface roughness 13 are liable to be caused in trench inner wall 9.

When dry etching is employed for forming trenches, the above described problems are caused commonly in almost all the semiconductor materials. The formations of amorphous SiC 11 and crystal damage 12 are avoided by employing wet etching. The impact energy of the reactant molecules in wet etching is about 26 meV at the room temperature and is not so high as to cause amorphous SiC 11 or crystal damage 12. However, it is impossible to form trenches 8, the crystal plane orientations of which are strictly defined, only by wet etching. For forming trenches 8, it is necessary to employ anisotropic etching. Since no etchant exists for wet etching SiC crystal, there is no choice but to employ dry etching. Thus, there exists no alternative but to employ the methods described below for avoiding the problems caused by the dry etching.

After forming trench 8 by dry etching, most of oxide residue 10 is removed with a hydrofluoric acid solution. However, it is not guaranteed that amorphous SiC 11 and particles 14 are satisfactorily removed with a hydrofluoric acid solution. In the process of cleaning with pure water and drying, the oxygen dissolved in the pure water and some oxygen atoms in the water molecules react with SiC, causing oxide residue 10 again. This oxide residue 10 remains on trench inner wall 9 after drying, causing a serious first problem. Water drops and particles 14 are liable to gather on the trench edges by the centrifugal force in spin-drying, causing serious contamination problems. These problems are more serious as the trench size becomes finer such that the planar patterns of the trenches are shaped with respective stripes of 1 μm or narrower in width. The trenches whose planar patterns are lattice shaped are assemblies of edges. If one compares the number of trench edges per unit area, the trenches whose planar patterns are lattice shaped include trench edges from a hundred times to thousands of times as dense as the stripe-shaped trenches, causing a serious second problem. These states are illustrated microscopically in FIG. 3 that is an expanded perspective view of a trench.

It has been known that the crystal plane that provides the SiC MOSFET with the highest channel mobility is the (03-38) plane of 4H—SiC. Therefore, it is preferable to arrange trenches 8 at the lattice points of a planar lattice on the (11-20) plane of the 4H—SiC crystal belonging to the hexagonal system as shown in FIG. 4 so that trench 8 may have side walls formed of the (03-38) plane of the 4H—SiC crystal or an equivalent crystal plane. However, this trench configuration causes the various kinds of serious contamination in trenches 8 due to the second problem of high trench edge density. FIG. 4(a) shows trenches 8 formed at the lattice points of a planar lattice on the (11-20) plane of the SiC crystal. FIG. 4(b) is a cross sectional view along the line segment A-A of FIG. 4(a). In FIG. 4(a), the arrows indicate the plane directions and the point in an open circle indicate the crystal plane direction perpendicular to the plane of paper.

The size of particles 14 in FIG. 3 falls almost within the range between 0.01 and 0.1 μm. If exceptionally large, the size of particles 14 will be 1 μm or less. In FIG. 3, all the contamination factors are exaggerated. Since particles 14 may be caused below oxide residue 10 or on oxide residue 10, it is necessary for the surface cleaning technique to remove particles 14 irrespective of whether particles 14 are below or on oxide residue 10.

FIG. 3 shows the limit of cleaning trench inner wall 8 by the conventional advanced surface treatment techniques applicable to the wafer (semiconductor substrate) in which trenches 8 are formed, such as cleaning with hydrofluoric acid, cleaning with pure water, sacrifice oxidation, plasma etching and chemical dry etching (CDE). Therefore, there is no choice but to conduct the next step of forming a gate oxide film on trench inner wall 9 in the state shown in FIG. 3, impairing the breakdown voltage and the reliability of the gate oxide film in the SiC semiconductor device having a trench MOS structure.

It is preferable to etch trench inner wall 9 a little bit by isotropic plasma etching to remove damage after forming trenches 8 and cleaning trenches 8 with a hydrofluoric acid solution. However, since effects equivalent or superior to the effects obtained by the above described damage removal are obtained by the surface treatment in a gas phase reaction furnace according to the invention, the above described damage removal by isotropic plasma etching may be omitted.

According to the first embodiment, SiC substrate 1, in which trenches 8 having the cross section shown in FIGS. 2(a) and 2(b) are formed at the lattice points of a planar lattice as shown in FIG. 4(a), is loaded into a gas phase reaction furnace (not shown). The gas phase reaction furnace is made of quartz tubing and such a material containing fewer contaminants. The gas phase reaction furnace includes a graphite susceptor, a heat insulator around the graphite susceptor, a gas inlet, a gas outlet, and an RF coil for heating the graphite susceptor from the outside of the furnace by high-frequency electromagnetic induction.

The surface of trench inner wall 9 is treated in the gas phase reaction furnace through any of the gas phase surface treatment steps (a) through (e) described below or through an appropriate combination of the surface treatment steps (a) through (e) to remove the particles and oxide residues.

Among the numerical values described below, the optimum flow rates (described in the SLM unit or the sccm unit), at which various gases are supplied to the reaction furnace, change depending on the furnace volume and the furnace shape. In other words, the optimum flow rates described below are exemplary and, therefore, may be changed within the scope of the invention.

The gas phase surface treatment step (a) is conducted in the following manner. The wafer temperature is set at 1500° C. or higher. The inside of the reaction furnace is in a hydrogen atmosphere under a reduced pressure between 50 and 200 Torr and hydrogen gas is always supplied at the flow rate of 10 SLM such that the SiC surface portion is etched for from several nm to 0.1 μm by the reaction of hydrogen and SiC. Since the SiC surface is etched and terminated with hydrogen, the other contaminant elements will be prevented from adhering to the SiC surface and increasing the surface state density, when SiC substrate 1 is taken out of the furnace and a gate oxide film is formed thereon.

The gas phase surface treatment step (b) is conducted in the following manner. The wafer temperature is set at 1500° C. or higher. The inside of the reaction furnace is in a hydrogen atmosphere under a reduced pressure between 50 and 200 Torr and HCl is added at the flow rate of from 1 to 100 sccm to hydrogen always made to flow at the flow rate of 10 SLM. The surface portion of a SiC substrate is etched for from several nm to 0.1 μm by the reaction of hydrogen and SiC and by the reaction of HCl and SiC. Since the SiC surface is etched vigorously by HCl, etched by hydrogen, and terminated by hydrogen, the other contaminant elements will be prevented from adhering to the SiC surface and increasing the surface state density, when SiC substrate 1 is taken out of the furnace and a gate oxide film is formed thereon. However, it is necessary to control the wafer temperature and the amount of HCl added carefully so that the dangling bonds may not be terminated by Cl, which is a very reactive halogen element.

The gas phase surface treatment step (c) is conducted in the following manner. The wafer temperature is set at 1500° C. or higher. The inside of the reaction furnace is in a hydrogen atmosphere under a reduced pressure between 50 and 200 Torr and C₃H₈ is added at a flow rate of from 1 to 10 sccm to hydrogen always made to flow at the flow rate of 10 SLM. The SiC surface portion is etched by several nm to 0.1 μm at a slightly slower etching rate by the reaction of hydrogen and SiC braked with C₃H₈. Since the SiC surface is etched more slowly as compared with the usual etching only by hydrogen, the gas phase surface treatment step (c) facilitates the maintenance of surface flatness. Since the SiC surface is terminated by hydrogen, the other contaminant elements will be prevented from adhering to the SiC surface and forming new surface levels, when SiC substrate 1 is taken out of the furnace and a gate oxide film is formed thereon.

The gas phase surface treatment step (d) is conducted in the following manner. The wafer temperature is set at 1500° C. or higher. The inside of the reaction furnace is in a hydrogen atmosphere under a reduced pressure between 50 and 200 Torr and SiH₄ is added at the flow rate of from 1 to 30 sccm to hydrogen always made to flow at the flow rate of 10 SLM. The SiC surface portion is etched for from several nm to 0.1 μm at a slightly slower etching rate by the reaction of hydrogen and SiC braked with SiH₄. Since the SiC surface is etched more slowly as compared with the usual etching only by hydrogen, the gas phase surface treatment step (d) facilitates the maintenance of surface flatness. Since the SiC surface is terminated by hydrogen, the other contaminant elements will be prevented from adhering to the SiC surface and forming new surface levels, when SiC substrate 1 is taken out of the furnace and a gate oxide film is formed thereon.

The gas phase surface treatment step (e) is conducted in the following manner. The wafer temperature is set at 1500° C. or higher. The inside of the reaction furnace is in a hydrogen atmosphere under a reduced pressure between 50 and 200 Torr. C₃H₈ and SiH₄ are added at the respective flow rates of from 1 to 30 sccm to hydrogen always made to flow at the flow rate of 10 SLM such that the etching caused by the reaction of hydrogen and SiC and the epitaxial film growth by C₃H₈ and SiH₄ compete each other. By setting the etching rate to be a little bit higher than the epitaxial film growth rate, the SiC surface portion is etched slowly for from several nm to 0.1 μm. Since the SiC surface is etched more slowly as compared with the usual etching only by hydrogen, the gas phase surface treatment step (e) facilitates the maintenance of surface flatness. Since the SiC surface is terminated by hydrogen, the other contaminant elements will be prevented from adhering to the SiC surface and forming new surface levels, when SiC substrate 1 is taken out of the furnace and a gate oxide film is formed thereon.

According to the first embodiment, surface treatment is conducted in the following manner. First, the gas phase surface treatment step (a) is conducted under the following conditions. The hydrogen flow rate is set at 10 SLM, the pressure inside the reaction furnace at the reduced 120 Torr, and the wafer temperature at 1800° C. An etching reaction occurs between the SiC semiconductor substrate and the gas phase hydrogen, resulting in an etching rate of from 20 μm/hour to 30 μm/hour. Since it is appropriate for the etched thickness of trench inner wall 9 to be from 10 nm to 0.1 μm, the treatment time is set to be from 1 to 20 seconds.

If the etching rate is a little bit too high, the wafer temperature will be set at 1700° C. Although the etching reaction occurs between the SiC semiconductor substrate and the gas phase hydrogen as described above, the etching rate remains between 5 μm/hour and 10 μm/hour. For etching trench inner wall 9 for from 10 nm to 0.1 μm in the same manner as described above, the treatment time is set to be from 10 to 70 seconds.

The changes caused in the states of trench 8 and trench inner wall 9 during the gas phase surface treatment step (a) are shown in FIGS. 5(a) through 5(e), which are cross sectional views of the trench. FIG. 5(a) shows the initial state. Due to the reducing and etching effects of hydrogen, oxide residue 10 and amorphous SiC layer 11 are removed and get thinner and thinner as shown in FIG. 5(b). A part of amorphous SiC layer 11 recrystallizes, returning to SiC crystals. As the gas phase surface treatment proceeds further, amorphous SiC layer 11 vanishes as shown in FIG. 5(c). Side etching is caused in the SiC crystals, which are underlayers for oxides residue 10 and particles 14, such that oxides residue 10 and particles 14 are removed finally as shown in FIG. 5(d). However, surface roughness 13 and the side etching traces cause unevenness in the surface of trench inner wall 9.

For removing the surface unevenness remaining in the trench shown in FIG. 5(d) and for obtaining a flattened trench inner wall as shown in FIG. 5(e), the gas phase surface treatment step (e) is conducted under the following conditions. The hydrogen flow rate is set at 10 SLM. SiH₄ is added to the hydrogen flow at the flow rate of 3 sccm and C₃H₈ at the flow rate of 1.5 sccm. The pressure inside the reaction furnace is set at the reduced 80 Torr and the wafer temperature at 1750° C. An etching reaction occurs between SiC and the gas phase hydrogen and epitaxial film growth is caused by SiH₄ and C₃H₈ simultaneously with the etching reaction. The etching reaction and the epitaxial film growth compete with each other, resulting in a zero etching rate and a zero film growth rate. This state is maintained for from 30 to 300 seconds.

If described microscopically, the gas phase surface treatment step (e) includes removal of several atomic layers in the surface portion of the SiC crystal due to the hydrogen etching effects and new atom adhesion to the SiC crystals due to the epitaxial film growth effects. The removal of several atomic layers and the new atom adhesion to the SiC crystal are repeated such that only the several atomic layers in the surface portion of the SiC crystal are replaced vigorously. If described macroscopically, the SiC crystal surface moves neither forward nor backward.

The replacement of several atomic layers in the SiC crystal surface portion is illustrated in FIGS. 6(a) through 6(c), which are cross sectional views showing the atom deposition states at an atomic level. Although the 4H—SiC crystal belonging to the hexagonal system is assumed according to the first embodiment, the crystal lattice is represented by squares in FIGS. 6(a) through 6(c) for the sake of simplicity. FIG. 6(a) shows unevenness caused in the crystal surface. FIG. 6(b) shows the reduced unevenness that is the result of etching the crystal surface. FIG. 6(c) shows the crystal surface that has been flattened by filling the concave portion in the crystal surface shown in FIG. 6(b) by epitaxial film growth. Contrary to the descriptions in FIGS. 6(a) through 6(c), just one cycle of etching and epitaxial film growth is not enough to flatten the crystal surface. In practice, the pertinent processes proceed simultaneously and are repeated many times. The etching preferentially removes concave and convex portions, in which bonds are weak. In contrast, the epitaxial films grow from the step kinks preferentially under the condition that two-dimensional nucleation does not occur. The crystal surface is flattened by the competitive effects of planing and filling while the film thickness is kept at a certain value. If only etching is employed without employing epitaxial film growth simultaneously, the film thickness will be reduced, although the resultant film may be flat.

As described above, the gas phase surface treatment step (e) is a surface flattening step consisting of etching and epitaxial film growth as shown in FIGS. 6(a) through 6(c). The gas phase surface treatment step (e) exhibits three effects. First, by replacing several atom layers in the SiC crystal surface portion vigorously, crystal damage 12 caused by trench etching is removed. Second, the crystal major surface and trench inner wall 9 stabilize in a state in which there are fewer dangling bonds, surface roughness 13 is removed, and surfaces flat at the level of an atomic layer level are obtained. Third, the right-angle portions and the high-curvature portions in the opening and the bottom of trench 8 are deformed so that they are flat due to the effect of reducing the dangling bonds in the crystal in total in the same way as described in connection with the second effect. In other words, the right-angle portions and the high-curvature portions in the opening and the bottom of trench 8 are deformed so that their curvatures are reduced. Therefore, as far as the right-angle portions and the high-curvature portions in the opening and the bottom of trench 8 are concerned, the surface flattening in the gas phase surface treatment step (e) causes macroscopic deformations that reduce the local curvatures in the trench and provide the trench with a more rounded shape.

These effects are described for silicon in a prior-art document (Ichiro MIZUSHIMA et al., “Formation of SON (silicon on nothing) structure using surface migration of silicon atoms” (in Japanese), OYO BUTURI (A monthly journal of The Japan Society of Applied Physics), Vol. 69, No. 10, (2000), pp. 1187-1191). Gallium nitride crystal exhibits similar effects as disclosed in the Publication of Unexamined Japanese Patent Application 2004-111766 cited in the above described prior-art document. However, the techniques described in the above described documents are different from the surface treatments according to the first embodiment of the invention in that the techniques described in the above described documents utilize mass transport.

In contrast, the surface flattening by the gas phase surface treatment step (e) utilizes a quasi-thermal-equilibrium state, in which the etching rate and the epitaxial film growth rate compensate each other to cause neither etching nor film growth, so that the crystal can be shaped closely with the shape obtained by the thermal equilibrium, the dangling bonds can be reduced in total in the entire crystal, and the high-curvature portions can be relaxed and rounded.

If the treatment temperature is raised from 1750° C. to 1800° C. and the flow rates of SiH₄ and C₃H₈ are increased in the surface flattening in the gas phase surface treatment step (e), the etching rate and the epitaxial film growth rate will increase, maintaining the equilibrium. Therefore, the same effects are obtained within a shorter treatment time.

If the treatment temperature is lowered from 1750° C. to 1700° C. and the flow rates of SiH₄ and C₃H₈ are decreased, the etching rate and the epitaxial film growth rate will decrease, resulting in a longer treatment time. However, a longer treatment time facilitates managing the time for controlling the curvature and the shape factor. Thus, the shape shown in FIG. 5(d) is smoothed as shown in FIG. 5(e) through the gas phase surface treatment step (e) as described above. If the results obtained ‘through’ the surface flattening shown in FIGS. 5(a) through 5(e) are illustrated macroscopically with reference to the cross sectional views, the shape of trenches 8 shown in FIG. 2(b) will change to the shape of trenches 8 shown in FIG. 7.

After the surface flattening treatment on the trench inner wall is over, the SiH₄ supply is stopped first, the temperature is lowered to 1300° C. at a rate of 1° C. per second, then the C₃H₈ supply is stopped, and the temperature is lowered down to the room temperature at a rate of 1° C. per second while maintaining the hydrogen atmosphere. Since the etching effect by hydrogen remains during the temperature lowering, the C₃H₈ supply is continued while the temperature is lowered down to 1300° C. to relax the etching effect. If the etching effect relaxation is still insufficient, it is effective to continue the SiH₄ supply down to about 1600° C. while reducing the SiH₄ flow rate.

Since the SiC crystal is exposed only to the hydrogen atmosphere while the temperature is lowered from 1300° C., the dangling bonds in the crystal surface are terminated completely by hydrogen. As the SiC substrate is taken out of the gas phase reaction furnace after the temperature has been lowered to room temperature, the SiC substrate is exposed to fresh air in the clean room and a natural oxide film is formed. Since the natural oxide film replaces the hydrogen-terminated surface formed stably, the natural oxide film quality is stabilized, variations are hardly caused between the wafers or between the lots, and excellent process stability and excellent process reliability are obtained.

Then, a sacrifice oxide film of from several nm to 0.1 μm is formed on trench inner wall 9 and the sacrifice oxide film is removed. For removing the sacrifice oxide film, hydrofluoric acid or a similar reagent is used and washing with pure water is conducted. Therefore, the contamination factors described earlier are caused again. However, since a clean surface is .obtained once in the gas phase reaction furnace, only the sacrifice oxide film formation causes contamination factors and the cumulative contamination caused through the preceding steps is prevented from being carried over. If remarkable contamination is caused in forming a sacrifice oxide film and in removing the sacrifice oxide film, the step of forming a sacrifice oxide film may be omitted.

Then, a gate insulator film 15 is formed on trench inner wall 9. Although various methods are applicable to forming a gate insulator film in the SiC MOSFET, the following four methods may be employed mainly:

gate oxide film formation by thermal oxidation;

gate oxide film formation by depositing an amorphous silicon thin film or a polysilicon thin film and by oxidizing the amorphous silicon thin film or the polysilicon thin film;

gate oxide film formation with an HTO and such a deposition-type oxide film; or

gate oxide film formation by forming a silicon nitride film, a ferroelectric film or other similar non-oxide film.

Since the invention relates to the surface treatment of a SiC crystal before forming a gate insulator film, any of the above described four methods may be employed for forming the gate insulator film with no problem. The step of forming a doped polysilicon gate electrode 16, the step of forming a second p⁺-type region 17, the step of forming an interlayer insulator film 18, the step of forming a source metal electrode 19, and the step of forming a drain electrode 20 may be conducted in the same manner as the well known counterpart steps for manufacturing a UMOSFET. Since these steps of forming are outside the scope of the invention, their descriptions are omitted. The cross sectional view of a final UMOSFET as completed is shown in FIG. 8.

### Second Embodiment

According to the first embodiment, the gas phase surface treatment is conducted on trench inner wall 9 to remove particles 14 and oxide residue 10 caused in trench 8 as shown in FIG. 3 in advance through the step of trench etching. Alternatively, the gas phase surface treatment may be conducted in a different way.

First, the gas phase surface treatment step (b) is conducted under the following conditions. The hydrogen flow rate is set at 10 SLM. HCl is added to the hydrogen flow at the flow rate of 3 sccm. The pressure inside the reaction furnace is set at the reduced 120 Torr and the wafer temperature is set at 1800° C. Etching reactions occur between the SiC crystal surface and hydrogen and between the SiC crystal surface and HCl. The etching rate is from 35 to 40 μm/hour. Since it is appropriate for the etched thickness of trench inner wall 9 to be from several tens of nm to 0.1 μm, the treatment time is set to be from 1 to 10 seconds.

If the etching rate is too fast, it is effective to lower the etching temperature. For example, the etching rate will be from 10 to 15 μm/hour if the etching temperature is set at 1700° C. The etching rate will be from 1 to 2 μm/hour, if the etching temperature is set at 1500° C. Thus, the treatment time may be adjusted considering the etching rate.

If the gas phase surface treatment step (b) is compared with the gas phase surface treatment step (a) according to the first embodiment, the gas phase surface treatment step (b) will facilitate obtaining a more vigorous etching effect by HCl. Therefore, oxide residue 10, amorphous SiC 11 and particles 14 may be removed more effectively. However, viewed from the atomic level, HCl may roughen the SiC surface due to the strong reactivity thereof. For smoothing the roughened surface, it is necessary to add the gas phase surface treatment step (e). Then, the gas phase surface treatment step (e) is conducted under the following conditions.

The hydrogen flow rate is set at 10 SLM. SiH₄ is added to the hydrogen flow at the flow rate of 3 sccm and C₃H₈ at the flow rate of 1.5 sccm. The pressure inside the reaction furnace is set at the reduced 80 Torr and the wafer temperature at 1750° C. An etching reaction occurs between SiC and gas phase hydrogen and epitaxial film growth is caused by SiH₄ and C₃H₈ simultaneously with the etching reaction. The etching reaction and the epitaxial film growth compete each other, resulting in a zero etching rate and a zero film growth rate. This state is kept for form 30 to 300 seconds.

The gas phase surface treatment according to the second embodiment exhibits the same effects as those of the gas phase surface treatment according to the first embodiment. The subsequent temperature lowering steps may be conducted in the same manner as according to the first embodiment.

### Third Embodiment

Since the invention relates to the steps of preliminary surface treatment in forming a MOS structure in the SiC crystal surface, application of the invention is not limited to the trench-gate MOSFETs as described in connection with the first and second embodiments. If a similar preliminary treatment is conducted prior to forming a MOS structure, it will be possible to provide an MOS structure for the planar-gate MOSFET with a high quality. Less contamination factors are caused in the usual planar gate structure than in the trench gate structure. In some kinds of planar gate structures, no contamination factor is caused. For example, it is considered that amorphous SiC layer 11, which is caused in forming a trench gate, is not caused usually in the process of manufacturing the planar gate MOSFET that does not include any trench etching step. It is considered that crystal damage 12 is not caused in the planar gate structure in the same way as described above. However, the possibility that the crystal defects caused by crystal substrate 1 are carried over to the surface of the semiconductor structure can not be denied. Although the crystal defect density is extremely low, it can not be said that there exists no crystal defect. Therefore, if the invention is applied to manufacturing some planar gate MOSFETs, certain effects may be obtained.

In the surface treatment for the planar gate MOSFET, it is desirable to restore the crystal quality in the surface portion by conducting the gas phase surface treatment step (e) after etching the crystal surface portion slowly for several tens nm through any of the gas phase surface treatment steps (a) through (d).

Thus, a method for manufacturing silicon carbide semiconductors devices has been described according to the present invention. Many modifications and variations may be made to the techniques and structures described and illustrated herein without departing from the spirit and scope of the invention. Accordingly, it should be understood that the methods] described herein are illustrative only and are not limiting upon the scope of the invention.

What is claimed is:

1. A method for manufacturing a SiC semiconductor device including a SiC semiconductor substrate, the method comprising:
treating the surface of the SiC semiconductor substrate with hydrogen in a reaction furnace at 1500° C. or higher and at a reduced pressure to etch the surface of the SiC semiconductor substrate by several nm to 0.1 μm; and then
forming a gate oxide film on the SiC semiconductor substrate.

2. The method according to claim 1, wherein the treating comprises supplying hydrogen as a carrier gas and adding HCl gas to the hydrogen carrier gas as an etching gas to etch the surface of the SiC semiconductor substrate.

3. The method according to claim 1, wherein the treating comprises supplying hydrogen as a carrier gas and adding C₃H₈ gas to the hydrogen carrier gas as an etching gas to etch the surface of the SiC semiconductor substrate.

4. The method according to claim 1, wherein the treating comprises supplying hydrogen as a carrier gas and adding SiH₄ gas to the hydrogen carrier gas as an etching gas to etch the surface of the SiC semiconductor substrate.

5. The method according to claim 1, wherein the treating comprises simultaneously (i) etching with C₃H₈ gas and SiH₄ gas in hydrogen as a carrier and (ii) growing an epitaxial film with the C₃H₈ gas and the SiH₄ gas in the hydrogen carrier, wherein the rate of the etching is faster than or equal to the rate of growing the epitaxial film.

6. The method according to claim 1, further comprising growing an epitaxial film with C₃H₈ gas and SiH₄ gas.

7. The method according to claim 2, further comprising growing an epitaxial film with C₃H₈ gas and SiH₄ gas.

8. The method according to claim 3, further comprising growing an epitaxial film with C₃H₈ gas and SiH₄ gas.

9. The method according to claim 4, further comprising growing an epitaxial film with C₃H₈ gas and SiH₄ gas.

10. The method according to claim 1, further comprising:
forming trenches for a trench-type MOS gate structure in the SiC semiconductor substrate prior to treating the surface of the SiC semiconductor substrate; and
forming gate oxide films on the SiC semiconductor substrate subsequent to treating the surface of the SiC semiconductor substrate.

11. The method according to claim 10, wherein
(i) the major surface of the SiC semiconductor substrate in which the trench-type MOS gate structure is formed comprises the (11-20) plane of the SiC crystal or a plane equivalent to the (11-20) plane, and
(ii) one or more side walls of the trench comprise the (03-38) plane of the 4H—SiC crystal for the semiconductor substrate or a plane having an orientation equivalent to the (03-38) plane, or one or more side walls of the trench comprise the (01-14) plane of the 6H—SiC crystal for the semiconductor substrate or a plane having an orientation equivalent to the (01-14) plane.
